(19) United States
(12) Patent Application Publication
(10) Pub. No.: US 2010/0195946 A1
(43) Pub. Date: Aug. 5, 2010

(54) COATED BEARING

(76) Inventors: Xiao Bo Zhou, PV Houten (NL); Armel Louis Doyer, Savonnieres (FR); Frank Berens, Saunay (FR)

Correspondence Address: SKF USA Inc., 890 Forty Foot Road, PO Box 352, Lansdale, PA, 19446, US

(21) Appl. No.: 12/452,894

(22) PCT Filed: Jul. 28, 2008
(86) PCT No.: PCT/EP2008/006216

§ 371 Date: Apr. 16, 2010

(30) Foreign Application Priority Data
Aug. 1, 2007 (EP) 07015131.1

(51) Int. Cl. F16C 33/66; C23C 16/513

(52) U.S. Cl. 384/462; 427/569

(57) ABSTRACT

The invention concerns a bearing assembly comprising an inner ring, an outer ring and rolling elements, the inner ring and outer ring being rotatably coupled by means of the rolling elements. The rolling elements are disposed on opposing raceways within a bearing cavity and are retained in a cage. The bearing is provided with a lubricant and further comprises at least one sealing element, mounted in an annular gap between the inner and outer ring. To prevent the lubricant adhering to predetermined surfaces within the bearing cavity which do not require lubrication, at least one of these predetermined surfaces is provided with an oleophobic coating. One advantage of the invention is that the lubricant ages less quickly, leading to improved bearing service life.

### TECHNICAL FIELD

The invention concerns a rolling element bearing assembly and is more particularly directed to a bearing with selectively coated components, to improve the lubrication performance within the bearing.

### BACKGROUND

If rolling element bearings are to operate reliably, they must be adequately lubricated to prevent direct contact between the rolling elements, raceways and cage (if present). Loss of lubrication function results in friction and wear, and will quickly lead to bearing failure. Most rolling element bearings are lubricated with oil or grease. Grease comprises base oil, such as a mineral oil, and a thickener, such as a metallic soap. In a grease-lubricated bearing, oil released from the grease forms a thin film that separates the contact between rolling element and bearing raceways. Several parameters influence lubrication performance in bearings, but two of the key factors are that the lubricant is retained within the bearing cavity and that the oil film between the rolling contacts is replenished.

Many solutions have been proposed to improve lubrication performance and conditions within a bearing. Such solutions concern, for example, improvements in the chemistry of the lubricant itself. Other solutions concern improvements in bearing seals, with regard to better lip or labyrinth design or better seal materials. The movement of lubrication is another parameter that affects performance. One method which has been proposed to control the movement is to machine grooved patterns on the surface of the raceways and/or the rolling elements

There is still room for improvement, however, with regard to lubricant replenishment of the rolling contact and loss of lubricant via leakage.

### SUMMARY

Grease adheres readily to surfaces. It has been found that grease tends to remain on surfaces within the bearing cavity which are not in dynamic contact, such as the bars on a cage that retains the rolling elements. Bearings may also be fitted with a sealing element to keep the lubricant within the bearing cavity and prevent the entry of contaminants. The bearing-side surface of such a sealing element is another surface that is not subject to dynamic contact and where grease tends to remain.

A commonly used mechanism to describe grease lubrication is that the grease acts as an oil reservoir, where the oil is slowly released into the region of rolling contact due to factors such as heat and vibration. After long-term bearing operation, tests performed on the grease adhering to e.g. the inner surface of a sealing element have shown that the grease is relatively fresh. In other words, little oil has been released that has contributed to the lubricant replenishment of the surfaces which are in dynamic contact. The remainder of the grease which does contribute to replenishment must therefore do more work, and ages more quickly

Thus, an object of the invention is to define a bearing assembly that enables improved lubricant replenishment within the bearing cavity.

A further object of the invention is to define a bearing assembly in which the lubricant is better retained within the bearing cavity.

A still further object of the invention is to define a method of treating a component of bearing assembly in order to achieve improved replenishment and retention of the lubricant within the bearing cavity.

The aforementioned objects are achieved according to the invention in a bearing assembly comprising an inner ring, an outer ring and rolling elements, the inner ring and outer ring being rotatably coupled by means of the rolling elements. The rolling elements are disposed on opposing raceways within a bearing cavity and are retained in a cage. The bearing is provided with a lubricant and further comprises a sealing element, mounted in an annular gap between the inner and outer ring. To prevent the lubricant adhering to predetermined surfaces within the bearing cavity which do not require lubrication, at least one of these predetermined surfaces is provided with an oleophobic coating.

Oleophobicity is defined in terms of the measured contact angle between a surface and droplet of oil thereon. Surfaces with a low contact angle are oleophilic and are said to have good wettability. Surfaces with a high contact angle are oleophobic and are said to have poor wettability. In the present invention, a surface is defined as oleophobic when the oil contact angle is greater than 45 degrees.

The materials from which the bearing rings, cage and sealing element are typically made all have good wetting properties with oil. High wettability is desired in the regions of rolling contact, but is not necessary in others areas within the bearing cavity which do not require lubrication.

Consequently, in a first embodiment of the invention, at least a predetermined surface of the bearing cage is provided with the oleophobic coating. A cage comprises pockets in which the rolling elements are arranged. The inner surfaces of cage pockets are in dynamic contact with the rolling elements, and the presence of a lubricant is desirable there. The predetermined coating surface is therefore selected from one or more of the cage surfaces, which are not in contact with the rolling elements, i.e. the inner and outer circumferential surfaces and/or the peripheral perpendicular surfaces of the cage (perpendicular to axis of rotation).

In an advantageous further development of this embodiment, the circumferential surfaces of the cage could be selectively coated with the oleophobic coating, so as to guide the lubricant towards the contacting surfaces of the cage pockets.

Another surface on which grease tends to adhere is on an axially inward surface of the sealing element. Thus, in a second embodiment of the invention, at least a portion of the axially inward side of the sealing element is provided with the oleophobic coating. The sealing element may be an integral seal or a replaceable, cartridge-type seal. An integral sealing element may be a non-contact seal, such as a shield or a low-friction seal. In a non-contact seal, a small gap remains between the surface of the rotating bearing ring and the sealing element. It is possible for lubricant to leak out via this gap. The integral sealing element may also be a contact seal, which seals against a shoulder or a recess in the shoulder of the rotating bearing ring. A contact seal generally comprises an elastomeric sealing lip that engages with the surface of the rotating bearing ring. If the sealing lip is subject to excessive wear or ageing, a gap may be created that could allow the leakage of lubricant.

Thus, in a third embodiment of the invention, at least a region of the rotating bearing ring is provided with the oleophobic coating, this region being delimited by an axially outer edge of the bearing raceway and an axially outer edge of the rotating bearing ring. The presence of an oleophobic surface here will help prevent the leakage of lubricant. Moreover, the oleophobic surface will also be hydrophobic and thereby further prevent the ingress of moisture and contaminants.

The bearing may also be sealed on at least one side by a cartridge-type seal assembly. A cartridge-type seal may comprise an elastomeric sealing lip and a flinger component. The flinger component comprises a cylindrical portion, which is mounted on the shoulder of the rotating bearing ring and serves as a counterface for the sealing lip, and comprises a radial flange portion, which dynamically repels contaminants.

In a further embodiment of the invention, the oleophobic coating is provided on at least part of a radially outward surface of the cylindrical portion of the flinger component. In a still further embodiment, the oleophobic coating is provided on at least part of an axially inward surface of the flange portion of the flinger component.

Other embodiments of the invention are envisaged in which the oleophobic coating is applied on other component surfaces within the bearing cavity which are not subject to dynamic contact. These non-contacting surfaces include: one or both ends of non-spherical rolling elements, such as cylindrical rollers or tapered rollers, and surfaces of the inner and/or outer ring, other than the raceways.

In an advantageous further development of the invention, the predetermined surface or surfaces could be provided with a coating having an oleophobicity gradient. For example, the inner ring could be coated so as to have maximum oleophobicity at the axially outer edge with decreasing oleophobicity towards the raceway. The advantage of this is that the lubricant would be entrained towards the raceway, i.e. the area where lubricant is most needed.

The stated objects of the invention are further achieved in that the oleophobic coating is a plasma polymer coating obtained by exposing a substrate to plasma polymerization. Plasma polymerization is a process by which a thin layer of polymeric film is deposited on the surface of a substrate, where the film is formed from a polymerizable precursor introduced into a plasma-forming gas. The precursor contains monomers, which are suitably selected to form a polymer coating with oleophobic properties. In order to preserve the functionality of the plasma polymer coating, it is produced by means of a non-equilibrium or cold plasma deposition process. One method of generating a cold plasma is to apply a voltage across a gas.

Consequently, a bearing assembly according to the invention is preferably produced by means of a cold plasma deposition process in which a plasma polymer coating is formed on a predetermined surface or surfaces of one more components of the bearing assembly. The process may be carried out at atmospheric pressure or in a low vacuum. At atmospheric pressure, the precursor may be in a liquid state. The liquid precursor is atomized and then sprayed into the plasma. The plasma converts the precursor into a coating, which is deposited on the surface of the component exposed to the plasma. Under vacuum conditions, of preferably 50-500 mTorr, the precursor will typically be in gaseous form.

The use of a plasma polymer coating is advantageous, firstly because a precursor with suitable properties may be selected and secondly because the plasma deposition process may be controlled to form a coating with the desired properties. Fluorocarbons are known for their oleophobicity, and thus, a bearing assembly according to the invention is preferably provided on a selected surface or surfaces with a fluorocarbon coating. More preferably, the terminal groups of the fluorocarbon coating have a composition ratio of carbon to fluor of 3:1 (CF3), such that the surface of the coating predominantly comprises CF3. This chemical composition is highly oleophobic. In tests to measure the contact angle with an oil, values in excess of 90 degrees have been achieved. At such high levels of oleophobicity, hardly any oil will remain on surfaces of a bearing that are provided with the coating. Grease will be easily dislodged and as a result, more lubricant will be available for replenishment on the surfaces where lubrication is needed.

The present invention also defines a method of depositing an oleophobic coating on a surface of a component of a bearing assembly, the method comprising the steps of:
(i) generating a cold plasma by applying a voltage across a gas,
(ii) introducing a fluorocarbon precursor into the plasma,
(iii) immersing the component surface in a resulting mixture of plasma and fluorocarbon precursor.

The method may also comprise a first and second pre-deposition step, conducted in the absence of the precursor. This first pre-deposition step is a cleaning step, in which the substrate is immersed in plasma alone, in order to remove surface contaminants and promote adhesion of the coating. The second pre-deposition step depends on whether the plasma deposition process takes place at atmospheric pressure or in a low vacuum, and also depends on the substrate material.

If the substrate is itself a polymer, e.g. a rubber sealing lip or a polyamide cage, and the deposition is conducted at atmospheric pressure, the second pre-deposition step is a surface activation step, whereby the substrate is further exposed to the plasma alone, to modify the surface layer. This surface modification can be applied to further improve the adhesion of the oleophobic coating.

When conducted in a low vacuum, the second pre-deposition step is a micro-etching step, whereby a very thin layer of material (in the region of a few nanometers) is removed from the surface, to further improve adhesion of the coating.

The present invention also defines a component of a bearing assembly, where the component is one or more of an inner ring, an outer ring, a cage, a rolling element, an integral sealing element or a component of a cartridge-type sealing element, and where at least a surface of the one or more components is provided with an oleophobic coating according to the inventive method.

The method according to the invention has several advantages. Firstly, the method enables the deposition of a coating that is highly oleophobic. Secondly, the method allows the oleophobic coating to be deposited on any type of material. This is particularly important with regard to a bearing assembly, given that its components may be made from different materials. The cage, for example, may be made of steel, brass or polyamide. The sealing element may comprise an elastomeric material. Thirdly, the oleophobic coating may be deposited in a thin film of between 10 and 100 nanometers, thereby leaving the bulk properties of the substrate material unaffected. Furthermore, the method is controllable.

A bearing assembly according to the invention, with one or more components provided with the oleophobic coating described above, also has several advantages.

These include: better retention of lubricant within the bearing cavity and better movement of lubrication within the bearing. As a result, the lubricant, grease in particular, will age less quickly. Improved lubrication performance is beneficial to bearing life.

Other advantages of the invention will become apparent from the detailed description

### BRIEF DESCRIPTION OF THE DRAWINGS

The invention will now be described in more detail for explanatory, and in no sense limiting, purposes, with reference to the following figures, in which

FIGS. 1a-1c illustrate sections of a rolling element bearing assembly according to embodiments of the invention,

FIGS. 2a-2b illustrate schematic views of cages which may form part of bearing assemblies according to the invention.

### DETAILED DESCRIPTION

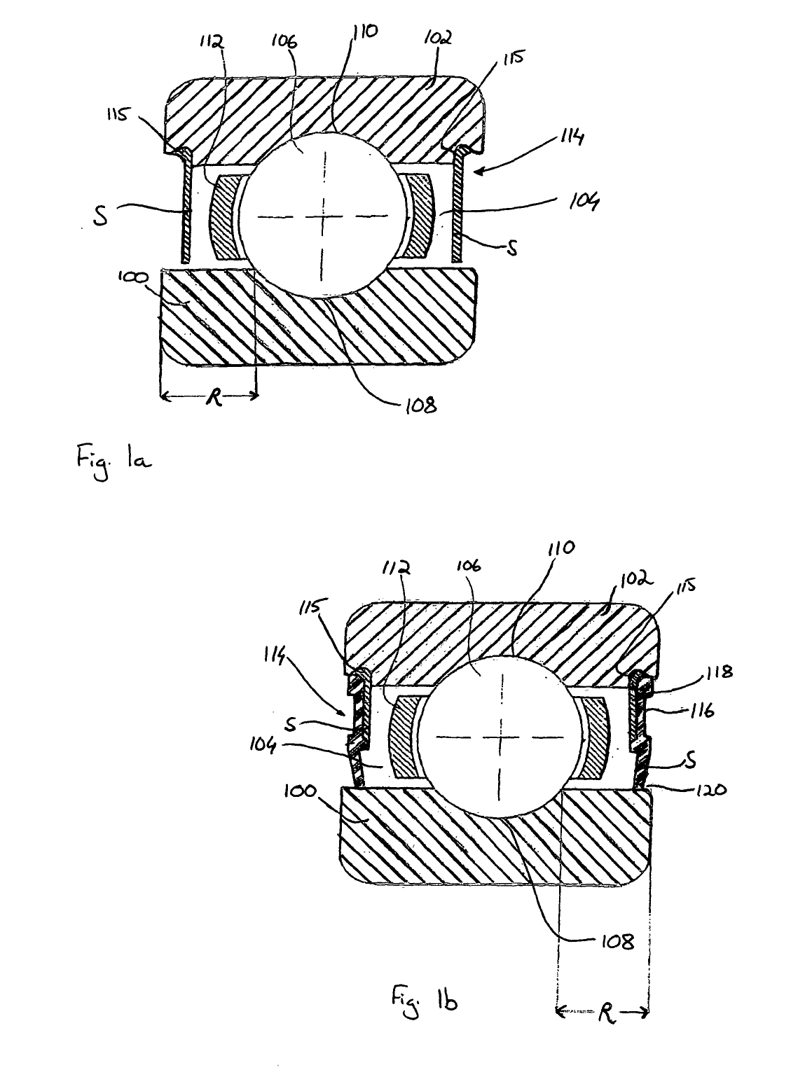

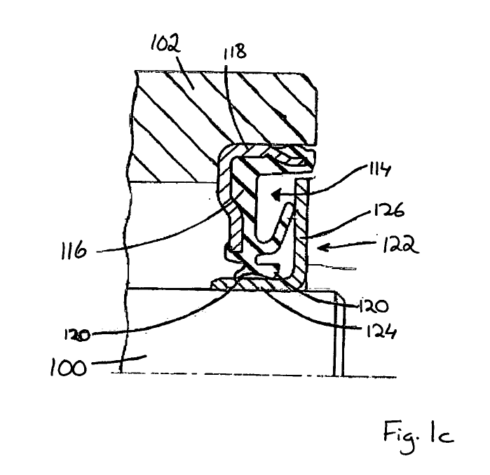

FIGS. 1a-1b illustrate embodiments of a bearing assembly according to the invention comprising an inner ring 100 and outer ring 102, between which a bearing cavity 104 is defined. The inner ring and outer ring are rotatably coupled by means of rolling elements 106, which are disposed on opposing raceways 108, 110 in the inner and outer ring respectively. The rolling elements are retained in a cage 112. To lubricate the rolling contacts during operation, the bearing is provided with a grease or oil lubricant (not shown). The bearing is further provided with at least one sealing component 114 mounted in a groove 115 in the outer ring 102, to at least substantially span the radial gap of the bearing cavity 104.

The illustrated embodiments are examples of bearings with a rotating inner ring and a non-rotating outer ring. This is the most common bearing arrangement, but the invention is also applicable to bearing arrangements where the outer ring is rotatable and the inner ring is held fixed.

In FIG. 1a, the sealing component 114 is an integral bearing shield. This is a non-contact type seal, which is applied when low friction is important, e.g. at high rotational speeds of the inner ring 100. The sealing component 114 has a surface S facing towards a radial centerline of the bearing. A shield is typically made from sheet steel, meaning that the surface S has excellent wettability. To substantially reduce the amount of lubricant that remains here, in a first embodiment of the invention, at least part of the surface S is provided with an oleophobic coating. A surface is defined as being oleophobic when the oil contact angle is greater than 45 degrees.

Because a shield is a non-contact seal, there is necessarily a small gap between its radially inner edge and the opposing surface of the inner ring. Loss of lubricant via leakage through this gap is possible. Thus, in a second embodiment of the invention, at least a portion of a region R on the surface of the inner ring is provided with the oleophobic coating. The region R is delimited by an axially outer edge of the raceway 108 and an axially outer edge of the inner ring 100. During operation, lubricant that is present in this region, especially towards the axially outer edge of the inner ring, is more likely to be flung out and escape via this gap, due to the action of e.g. centrifugal forces and vibration. If at least part of the region R is treated with the oleophobic coating, less lubricant will remain here, leading to reduced leakage losses. Moreover, an oleophobic material is also hydrophobic. As a result, the ingress of moisture and water vapour contaminants is further prevented, which is an added advantage of this second embodiment of the invention.

The sealing component may also be an integral bearing seal, as shown in FIG. 1b. This is a contact type seal, which generally comprises an elastomeric body 116, reinforced by a sheet metal casing 118. The seal further comprises at least one sealing lip 120 that bears against the rotating bearing ring 100. If excessive wear occurs, a gap can be formed between the lip and the opposing surface of the rotating bearing ring 100. As described above, lubricant may escape via this gap. Therefore, it is also advantageous to provide the oleophobic coating on at least a portion of the region R. Likewise, the surface S of the elastomeric body 116 may be provided with the oleophobic coating. This is particularly advantageous for elastomeric materials, as it is possible for oil molecules to permeate through the elastomer matrix.

The sealing component may also be a cartridge type seal. Such a seal is shown in FIG. 1c. The seal comprises an elastomeric body 116 that is bonded to a metal casing 118, which casing is mounted to the non-rotating bearing ring 102 The elastomeric body has at least one sealing lip 120 that engages a cylindrical portion 124 of a flinger component 122. The cylindrical portion 124 is mounted on the rotating bearing ring 100 and is in dynamic contact with the sealing lip 120. The flinger component further comprises a radial flange portion 126, which dynamically repels contaminants.

In a bearing assembly according to the invention that comprises a cartridge type seal, the oleophobic coating may be provided on a portion of one or more surfaces of the cartridge type seal. These surfaces include: the surfaces of the sheet metal casing 118 facing towards the radial centerline of the bearing; the surfaces of the elastomeric body 116 and sealing lip 120; a radially outer surface of the cylindrical portion 124; an axially inner surface of the flange portion 126. Providing one or more of these component surfaces with an oleophobic coating delivers the same advantages as described above for an integral bearing seal.

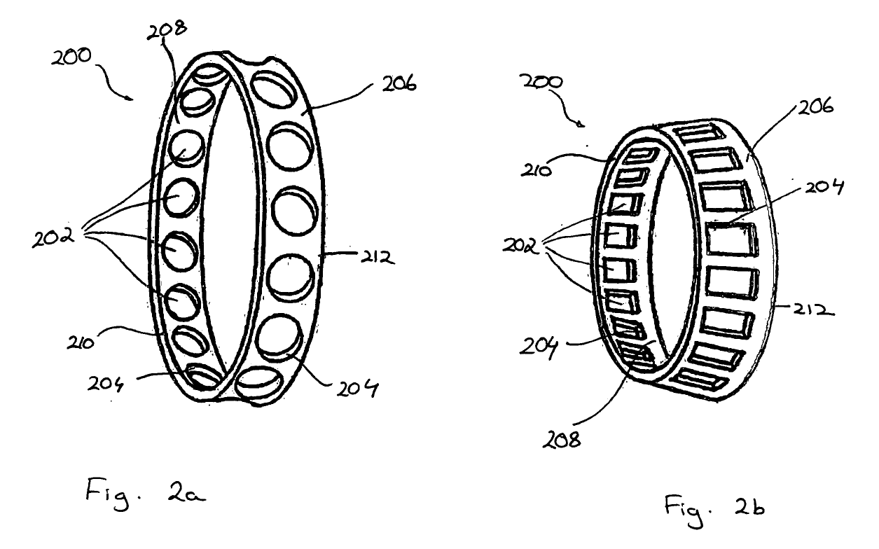

In a further embodiment of a bearing assembly according to the invention, parts of the cage are provided with the oleophobic coating. FIGS. 2a and 2b show schematic views of bearing cages 200, suitable for a ball bearing and a taper roller bearing respectively. A cage comprises pockets 202 in which the rolling elements are arranged. The surfaces 204 of cage pockets are in dynamic contact with the rolling elements, and the presence of a lubricant is desirable here. The pockets are interlinked by cage bars having first 206 and second 208 circumferential surfaces and first 210 and second 212 perpendicular peripheral surfaces (perpendicular to cage axis of rotation). The circumferential surfaces 206, 208 and the perpendicular surfaces 210, 212 are not in dynamic contact with other components, and to prevent excess lubricant remaining thereon, at least a part of one or more of these non-contacting surfaces is provided with the oleophobic coating.

According to the invention, the oleophobic coating is preferably a plasma polymer coating provided by means of a cold plasma deposition process. More preferably, the coating is a fluorocarbon coating comprising terminal groups with a carbon to fluor ratio of 1:3 (CF3), as such a chemical composition is highly oleophobic. One method of providing a component of a bearing assembly with the oleophobic coating is as follows.

The component, e.g. a bearing cage, is placed directly or indirectly on a first electrode plate in a process chamber of plasma deposition equipment. The chamber is evacuated to a pressure of approximately 50-500 mTorr, and a gas is introduced, for example argon. A fluorocarbon precursor in gaseous form is then introduced and mixed with the argon. A high voltage is applied across the first electrode plate and a second electrode, igniting a plasma. The fluorocarbon precursor is broken down into polymerizable monomers which, under the action of the plasma, form a coating on the exposed surfaces of the bearing component. The process lasts only a few seconds to form a coating of preferably 10-100 nanometers in thickness.

The contacting surfaces of the cage, i.e. the pocket surfaces, could be masked prior to deposition of the coating. Alternatively, the coating could be mechanically removed from selected surfaces. The fluorocarbon coating is a soft coating and although the plasma deposition results in excellent adhesion, it will wear off quite quickly when subjected to rolling contact with e.g. a steel roller. Thus, in a preferred embodiment of the method, for reasons of speed and economy, the fluorocarbon coating is deposited on the entire cage. When the cage is in use in an assembled bearing, the oleophobic coating will be quickly removed by the action of the dynamic contact with the rolling elements. The same procedure can be applied to other components of a bearing assembly, such as the inner and outer ring, the sealing lip, the flinger component of a cartridge-type seal etc.

Thus, a component of a bearing assembly may be provided with an oleophobic coating, resulting in a bearing with improved performance in terms of lubricant retention and lubricant re-use. A number of aspects/embodiments of the invention have been described. It is to be understood that each aspect/embodiment may be combined with any other aspect/embodiment. Moreover the invention is not restricted to the described embodiments, but may be varied within the scope of the accompanying patent claims.

### REFERENCE SIGNS

FIGS. 1a-1c illustrate a section of bearing assemblies according to different embodiments of the invention,
100 inner ring,
102 outer ring,
104 bearing cavity,
106 rolling elements,
108, 110 raceway,
112 cage,
114 sealing component,
115 groove,
116 elastomeric body
118 seal casing
120 sealing lip
122 flinger component,
124 cylindrical portion,
126 flange portion,
S axially inner surface of sealing component,
R region of rotating bearing ring.

FIGS. 2a-2b illustrate schematic views of bearing cages,
200 cage,
202 pockets,
204 pocket surfaces
206, 208 circumferential surfaces,
210, 212 perpendicular peripheral surfaces.

1. A bearing assembly comprising:
an inner ring component,
an outer ring component,
a plurality of rolling element components disposed between the inner and outer ring components on at least one set of opposing raceways within a bearing cavity, the inner ring component and outer ring component being rotatably coupled by the rolling element components, and
an oleophobic coating disposed on at least one surface within the bearing cavity of at least one of the inner ring component, the outer ring component, and the rolling element components.

2. The bearing assembly according to claim 1, wherein the bearing assembly further comprises a cage component configured to guide and retain the rolling element components within the bearing cavity.

3. The bearing assembly according to claim 1, wherein the bearing assembly further comprises an oil or grease lubricant and at least one sealing component mounted in an annular gap defined between the inner ring and outer ring components.

4. The bearing assembly according to claim 1, wherein the oleophobic coating has an oil contact angle of greater than 45 degrees.

5. The bearing assembly according to claim 1, wherein the at least one coated surface is free from contact with other component surfaces.

6. The bearing assembly according to claim 2, wherein the oleophobic coating is provided on a surface of the cage component.

7. The bearing assembly according to claim 3, wherein the oleophobic coating is provided on at least a portion of an axially inward surface of the sealing component.

8. The bearing assembly according to claim 3, wherein the sealing component is an integral sealing element.

9. The bearing assembly according to claim 3, wherein the sealing component is a cartridge-type seal assembly including a flinger component.

10. The bearing assembly according to claim 9, wherein the oleophobic coating is provided on at least part of a radially outward surface of a cylindrical portion of the flinger component.

11. The bearing assembly according to claim 9, wherein the oleophobic coating is provided on at least part of an axially inward surface of a radial flange portion of the flinger component

12. The bearing assembly according to claim 1, wherein the oleophobic coating is provided on at least part of a region of the inner ring component, where the region being located between an axially outer edge of the inner ring component and an axially outer edge of the inner ring raceway.

13. The bearing assembly according to claim 1, wherein the oleophobic coating is formed by a plasma deposition process.

14. The bearing assembly according to claim 13, wherein the plasma is generated by applying an electric field across a gas.

15. The bearing assembly according to claim 13, wherein the plasma deposition process is conducted at atmospheric pressure.

16. The bearing assembly according to claim 13, wherein the plasma deposition process is conducted within a vacuum.

17. The bearing assembly according to claim 1, wherein the oleophobic coating is a fluorocarbon coating.

18. The bearing assembly according to claim 17, wherein an outer surface of the fluorocarbon coating generally has a composition ratio of carbon to flourine of about 3:1.

19. The bearing assembly according to claim 1, wherein the oleophobic coating is deposited with a thickness of between about 1 nanometer and about 1000 nanometers.

20. A method of providing a surface of a component of a bearing assembly with an oleophobic coating, the method comprising the steps of:
(i) generating a cold plasma by means of applying a voltage across a gas,
(ii) introducing a fluorocarbon precursor into the plasma, and
(iii) immersing the surface of the bearing component in a resulting mixture of plasma and fluorocarbon precursor.

21. A component of a bearing assembly comprising:
at least one of an inner ring component, an outer ring component, a cage component, a rolling element component, an integral sealing component, and a component of a cartridge-type seal assembly; and
an oleophobic coating disposed on at least one surface of the at least one component, the coating being formed by:
(i) generating a cold plasma by means of applying a voltage across a gas,
(ii) introducing a fluorocarbon precursor into the plasma, and
(iii) immersing the surface of the at least one bearing component in a resulting mixture of plasma and fluorocarbon precursor.
